(19) United States
(12) Patent Application Publication
(10) Pub. No.: US 2010/0129524 A1
(43) Pub. Date: May 27, 2010

(54) METHODS OF DISPENSING POWDER COATING COMPOSITIONS AND ARTICLES COATED THEREWITH

(76) Inventors: Steven Sternberger, Pittsburgh, PA (US); Carol R. Jackson, Pittsburgh, PA (US); David R. Cremeans, Medina, OH (US); Calum H. Munro, Wexford, PA (US); Dennis L. Faler, North Huntingdon, PA (US); Joseph M. Ferencz, Litchfield, OH (US); William David Polk, Pittsburgh, PA (US)

Correspondence Address: PPG INDUSTRIES INC;INTELLECTUAL PROPERTY DEPT, ONE PPG PLACE, PITTSBURGH, PA, 15272, US

(21) Appl. No.: 12/622,893

(22) Filed: Nov. 20, 2009

Related U.S. Application Data
(63) Continuation-in-part of application No. 11/337,016, filed on Jan. 20, 2006.
(60) Provisional application No. 61/118,761, filed on Dec. 1, 2008.

(51) Int. Cl. C23C 16/52; B05D 3/02; B65D 83/06

(52) U.S. Cl. 427/8; 427/385.5; 222/129

(57) ABSTRACT

Disclosed are methods of dispensing thermoset powder coating compositions comprising a colorant, a particulate film-forming resin, and a curing agent for the film-forming resin, methods of coating substrates with powder coating compositions dispensed according to such methods, and systems for dispensing such powder compositions.

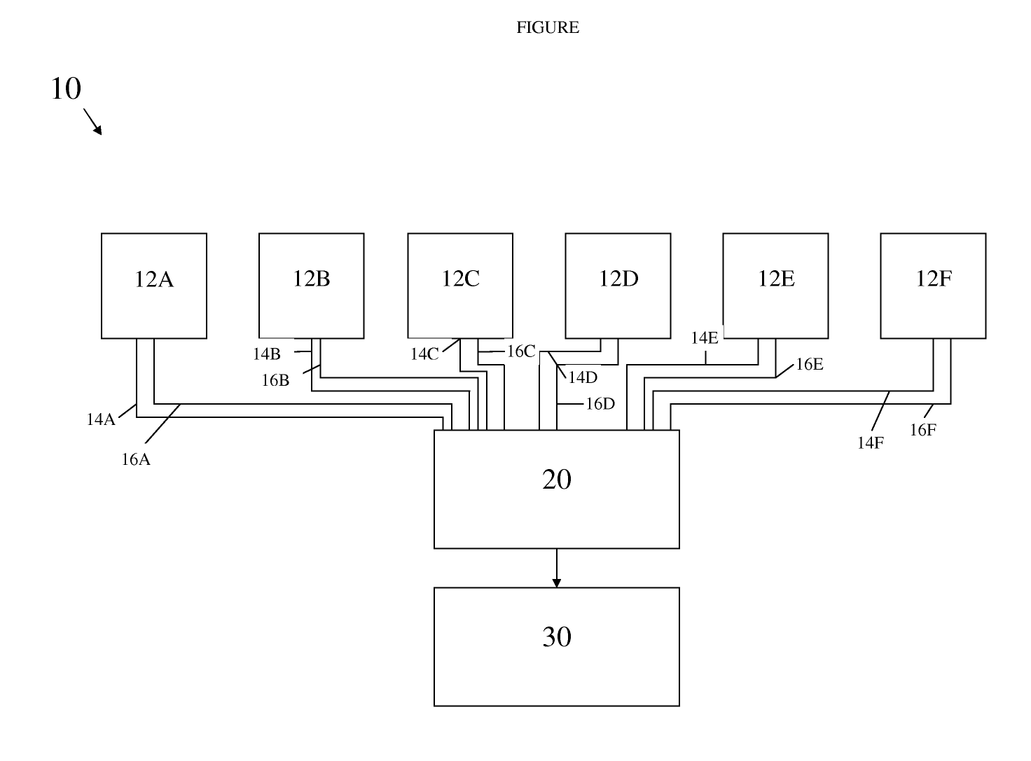

### CROSS-REFERENCE TO RELATED APPLICATIONS

This application is a continuation-in-part of U.S. patent application Ser. No. 11/337,016, entitled “Decorative And Durable Coatings Having A Homogeneous Hue, Methods For Their Preparation, And Articles Coated Therewith”, filed Jan. 20, 2006, incorporated herein by reference. This application also claims priority under 35 U.S.C. §119 to Provisional Application Ser. No. 61/118,761, filed Dec. 1, 2008, incorporated herein by reference.

### FIELD OF THE INVENTION

The present invention relates to methods of dispensing thermoset powder coating compositions, a system for dispensing a plurality of thermoset powder coating compositions, and methods of coating substrates with the dispensed thermoset powder coating compositions.

### BACKGROUND INFORMATION

Powder coatings compositions for use in coating various types of substrates are often desired. Such coating compositions can greatly reduce, or even eliminate, the use of organic solvents that are often used in liquid coating compositions. When a powder coating composition is cured by heating, little if any volatile material is driven into the surrounding environment. This is a significant advantage over liquid coating compositions in which organic solvent is volatized into the surrounding atmosphere when the coating composition is cured by heating.

Powder coating compositions are typically produced by a complex process that includes dry blending various coating components, such as color pigments, film-forming resins, curing agents, and other additives, such as flow control agents and charge control agents, subjecting the resulting blend to heating, melting and kneading by the use of an extruder or the like, and then subjecting the resulting extrudate to cooling, grinding and classification (referred to herein as the “Extrusion Process”). Thus, the Extrusion Process requires many steps.

Many customers, such as those customers in the industrial business, change colors frequently in production during the coating process. Often, customers wish to make these color changes in a short period of time. One disadvantage to the use of powder coatings has been the difficulty of coatings' manufacturers to produce and supply small batches of powder coating compositions in a variety of colors to customers in a short period of time and in a cost effective manner so that the customers can in turn rapidly change colors during production.

Another disadvantage to the use of powder coating compositions has been that, to obtain various coatings of different hues, the production of a separate powder coating composition for each desired hue has been required. When liquid coating compositions of different hues are mixed, it is possible to obtain a coating having a homogeneous hue that is different from the hue of each mixed liquid coating composition. On the other hand, when typical powder coating compositions of different hues are dry-blended and the resultant blend applied to a substrate, the result is that each hue can be generally distinguished by visual examination with the naked eye, resulting in a “salt and pepper” effect. Thus, it has previously been difficult, if not impossible, to achieve a coating of a desired hue from a dry blend of two or more powder coating compositions of different hues.

As a result, it would be desirable to have a method of dispensing a plurality of powder coating compositions to provide small batches of powder coating compositions in a variety of colors to the customer in a very short period of time. It would also be desirable to provide powder coating compositions suitable for producing a decorative and durable coating having a selected homogeneous hue from a dry blend of two or more powder coating compositions each having a different hue dispensed according to these methods.

### SUMMARY OF THE INVENTION

In certain respects, the present invention provides a method of dispensing a thermoset powder coating composition, comprising: metering a controlled amount of at least one of a plurality of thermoset powder coating compositions from at least one of a plurality of containers to a common receptacle, wherein at least one of the plurality of thermoset powder coating compositions comprises: (a) a colorant; (b) a particulate film-forming resin; and (c) a curing agent for the film-forming resin, and wherein each one of the thermoset powder coating compositions provides a finished decorative and durable coating when deposited onto a substrate and cured.

In other respects, the present invention a method of dispensing a plurality of thermoset powder coating compositions, comprising: metering a controlled amount of a first thermoset powder coating composition having a first hue from a first container and a second powder coating composition having a second hue different from the hue of the first powder coating composition from a second container to a common receptacle to form a mixture, wherein the first powder coating composition and the second powder coating composition each comprise: (a) a colorant; (b) a particulate film-forming resin; and (c) a curing agent for the film-forming resin, wherein each of the first thermoset powder coating composition and the second thermoset powder coating composition provides a finished decorative and durable coating when deposited onto a substrate and cured, and wherein the mixture provides a finished decorative and durable coating having a homogeneous hue different from the hue of the first powder coating composition and the hue of the second powder coating composition when the mixture is applied to a substrate and cured.

In yet other respects, the present invention is directed to a system for dispensing a plurality of thermoset powder coating compositions, the system comprising: (a) a plurality of containers having at least one thermoset powder coating composition therein; and (b) a means for metering a controlled amount of at least one of the thermoset powder coating compositions from at least one of the containers to a common receptacle, wherein the thermoset powder coating compositions comprise: (i) a colorant; (ii) a particulate film-forming resin; and (iii) a curing agent for the film-forming resin, and wherein each one of the thermoset powder coating compositions provides a finished decorative and durable coating when deposited onto a substrate and cured.

These and other respects will become more apparent from the following description.

### BRIEF DESCRIPTION OF THE DRAWINGS

The Figure schematically illustrates a system and method of metering and dispensing a plurality of thermoset powder coating compositions in accordance with an embodiment of the invention.

### DETAILED DESCRIPTION

For purposes of the following detailed description, it is to be understood that the invention may assume various alternative variations and step sequences, except where expressly specified to the contrary. Moreover, other than in any operating examples, or where otherwise indicated, all numbers expressing, for example, quantities of ingredients used in the specification and claims are to be understood as being modified in all instances by the term “about”. Accordingly, unless indicated to the contrary, the numerical parameters set forth in the following specification and attached claims are approximations that may vary depending upon the desired properties to be obtained by the present invention. At the very least, and not as an attempt to limit the application of the doctrine of equivalents to the scope of the claims, each numerical parameter should at least be construed in light of the number of reported significant digits and by applying ordinary rounding techniques.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard variation found in their respective testing measurements.

Also, it should be understood that any numerical range recited herein is intended to include all sub-ranges subsumed therein. For example, a range of “1 to 10” is intended to include all sub-ranges between (and including) the recited minimum value of 1 and the recited maximum value of 10, that is, having a minimum value equal to or greater than 1 and a maximum value of equal to or less than 10.

In this application, the use of the singular includes the plural and plural encompasses singular, unless specifically stated otherwise. In addition, in this application, the use of “or” means “and/or” unless specifically stated otherwise, even though “and/or” may be explicitly used in certain instances.

As previously mentioned, certain embodiments of the present invention are directed to methods of dispensing a plurality of thermoset powder coating compositions. As used herein, the term “thermoset” refers to compositions that set irreversibly upon curing or crosslinking wherein the polymer chains of the polymeric components are joined together by covalent bonds. As used herein, the term “powder coating compositions” refers to compositions suitable for producing a coating on a substrate, which is embodied in a solid particulate form, as opposed to liquid form.

In certain embodiments, the methods of the present invention comprise metering a controlled amount of at least one of a plurality of thermoset powder coating compositions from at least one of a plurality of containers to a common receptacle, wherein at least one of the plurality of thermoset powder coating compositions comprises: (a) a colorant; (b) a particulate film-forming resin; and (c) a curing agent for the film-forming resin, and wherein each one of the thermoset powder coating compositions provides a finished decorative and durable coating when deposited onto a substrate and cured.

Any suitable dispensing apparatus may be used to meter the thermoset powder coating compositions according to the methods of the present invention. Various types of dispensing apparatus include dispensers with rotating screws, pistons, and pumps. Examples of suitable dispensing apparatus include, but are not limited to, those available from IDEX Corporation and Fast & Fluid Management (a division of IDEX Corporation), for example, under the tradenames ACCUTINTER, XFAST, BLENDORAMA, COLORPRO, TINTMASTER, HARBIL, and LEOLUX. Non-limiting suitable dispensing apparatus that may be used to meter the thermoset powder coating compositions in accordance with the invention include those disclosed in U.S. Pat. No. 7,134,573, col. 3, line 13 through col. 5, line 6, the cited portion incorporated herein by reference, and U.S. Pat. No. 7,311,223, col. 3, line 32 through col. 7, line 11, the cited portion incorporated herein by reference. U.S. Pat. Nos. 7,134,573 and 7,311,223 disclose a dispensing apparatus with several containers, each container having a meter pump with two screws, a large and small screw, capable of dispensing powdered materials into a common receptacle. The plurality of containers and common receptacle described in U.S. Pat. Nos. 7,134,573 and 7,311,223 may be adapted and used in the methods of the present invention. The plurality of metering powder pumps as described in U.S. Pat. Nos. 7,134,573 and 7,311,223 may be used herein to meter a controlled amount of the thermoset powder coating compositions. The screws located inside the metering pumps as described in U.S. Pat. Nos. 7,134,573 and 7,311,223 may also be used in the metering step described herein to meter a controlled amount of the thermoset powder coating compositions.

Other suitable dispensing apparatus that may be used to meter the thermoset coating powders in accordance with the invention include those disclosed in U.S. Pat. No. 7,360,564, col. 4, line 47 through col. 9, line 32, the cited portion incorporated herein by reference.

The Figure schematically illustrates a system and method of metering and dispensing a plurality of thermoset powder coating compositions in accordance with an embodiment of the present invention. The system 10 can include multiple containers 12A-F, each of which contains at least one thermoset powder coating composition that can be the same or different. In certain embodiments, at least two, or, in some cases all, of the thermoset powder coating compositions have a different hue. The powder coating compositions are selectively fed from the containers 12A-F to a common receptacle 20. In the embodiment shown in the Figure, each container has a coarse feedline and a fine feedline extending from the container to the common receptacle 20. For example, the container 12A communicates with a first feedline 14A and a second feedline 16A. The first feedline 14A may be used to meter a coarse amount of the powder coating composition to the common receptacle 20, while the second feedline 16A may be used to meter a fine amount of the powder coating composition to the common receptacle 20. Each of the containers 12A-F are thus equipped with a coarse feedline 14A-F and a fine feedline 16A-F, respectively. As shown in the Figure, after the selected types and amounts of powder coating compositions are fed to the common receptacle, the powders may be fed to a powder coating sprayer for application to various substrates by known techniques, such as electrostatic spray deposition. A mixer (not shown) may be used to blend the multiple powder coating compositions prior to feeding the mixture to the powder coating sprayer 30.

There may be any number of containers present to hold the plurality of thermoset powder coating compositions in the methods of the present invention. The number of containers may vary depending on, for example, the number of thermoset powder coating compositions to be dispensed, and other similar factors. In certain embodiments, there may be a small number of containers, for example, up to ten containers, while in other embodiments, there may be a larger number of containers, for example, more than ten containers, such as twenty containers, in some cases, thirty containers.

In certain embodiments, each of the plurality of containers has one thermoset powder coating composition therein. In certain embodiments, the thermoset powder coating composition in each one of the containers is different from the thermoset powder coating composition in the other containers. In other embodiments, the thermoset powder coating composition differs from the other thermoset powder coating compositions in hue, as discussed in more detail below.

In other embodiments, each of the plurality of containers has two or more thermoset powder coating compositions therein.

The containers may be any suitable size and shape and may have the capacity to hold any suitable amount of thermoset powder coating composition. The containers may be covered or uncovered by any suitable means and may be made of any suitable material including but not limited to, plastic, metal, for example, stainless steel, aluminum, and the like.

In certain embodiments, the containers may have an associated mixing apparatus so that the thermoset powder coating compositions may be agitated while present inside the containers prior to being dispensed. In other embodiments, the containers themselves may be capable of rotation and/or vibration to agitate the powder coating compositions held within the containers. In still other embodiments, the containers do not require any such mixing apparatus.

In certain embodiments, the containers may have a heating apparatus associated with them, for example, to provide heat to the thermoset powder coating compositions provided the temperature does not reach a level that would prematurely soften and/or melt the powder coating compositions present inside the containers. In other embodiments, no such heating apparatus is required.

In certain embodiments, the containers may be portable, while in other embodiments, they may be non-portable.

In certain embodiments, the containers may be disposable. In these embodiments, once the thermoset powder coating composition held inside the container is used and the empty container is no longer desired, it may be discarded. A different container filled with the same or different thermoset powder coating composition may be used in its place. The disposable containers filled with thermoset powder coating composition may be provided by any suitable supplier, for example, by the manufacturer of the thermoset powder coating compositions or a third party supplier. The containers may be provided individually, i.e., a single full disposable container may be obtained to replace a single empty one. The containers may also be provided as a kit, i.e., a kit of more than one container may be obtained, the disposable containers in the kit filled with a variety of thermoset powder coating compositions having different hues. As used herein, the term “kit” refers to a collection of articles usable together. As used herein, the term “hue” refers to the quality of a color, as determined by its dominant wavelength. For example, the kits may comprise (a) a first container comprising a powder coating composition having a first hue, and (b) a second container comprising a powder coating composition having a second hue different from the first hue. There may be additional containers containing thermoset powder coating compositions of other different hues. The kits are discussed in more detail below. In other embodiments, the disposable containers may be filled with an additive that may be used in combination with the thermoset powder coating compositions in the methods of the present invention as discussed in further detail below.

In other embodiments, the plurality of containers used in the methods of the present invention may be refillable. In these embodiments, once the thermoset powder coating composition is used, the container may be refilled, i.e., more powder coating composition, either the same or different, may be added to the container. Any suitable method for refilling the containers may be employed.

As mentioned, at least one of a plurality of thermoset coating compositions is metered from at least one of a plurality of containers. Containers may also be present which hold materials other than the thermoset powder coating compositions. In certain embodiments, there may be additive containers, wherein the additive container holds at least one additive selected from a flatting agent, a UV absorber, a texture agent, a catalyst, a flow control agent, a charge control agent, a mar resistant agent, a flame retardant, an anti-microbial additive, an electrochromic particle, an effect pigment, and a mixture thereof.

As used herein, the term “effect pigment” refers to a material that provides visual effects to a coating and includes, but is not limited to, micas, metallic pigments, and the like. As used herein, the term “electrochromic particle” refers to a material that causes a color change in a coating in response to an applied electrical potential. Such materials are known in the art.

The additives are not necessary for the powder coating compositions to provide a finished decorative and durable coating when deposited onto a substrate and cured, as discussed in more detail below. The additives may optionally be added to the thermoset powder coating compositions to provide a variety of appearance and/or performance properties. Some of these additives may not be present for the purpose of providing appearance and/or performance properties to the powder compositions, but may be present for other purposes associated with the methods of the present invention, such as solvent used to clean the containers.

As mentioned, the methods of the present invention comprise metering a controlled amount of at least one of a plurality of thermoset powder coating compositions from at least one of a plurality of containers to a common receptacle. The thermoset powder coating composition is dispensed, in a controlled amount, from the container which holds it to the common receptacle. In certain embodiments, the amount of the thermoset coating composition dispensed is selectably controlled so that a particular chosen amount may be dispensed.

In certain embodiments, a single thermoset powder coating composition may be dispensed in a controlled amount from the container that holds it to the common receptacle, while in other embodiments, two or more of the thermoset powder coating compositions may be dispensed in controlled amounts from their individual containers to the common receptacle.

The common receptacle may have any of the characteristics described above with respect to the containers. Similar to the containers, the common receptacle may have an associated mixing apparatus so that the thermoset powder coating compositions may be agitated after being dispensed into the common receptacle. In other embodiments, the mixing apparatus is not necessarily associated with the common receptacle, but may exist separately from the common receptacle and used as necessary. In these embodiments, the common receptacle containing the plurality of thermoset coating compositions may be taken to a separate mixing apparatus and mixed prior to application to a substrate. In still other embodiments, the common receptacle may be capable of rotation and/or vibration to agitate the thermoset powder coating compositions that have been dispensed. In yet other embodiments, no mixing apparatus is present.

In certain embodiments, a heating apparatus may be associated with the common receptacle that provides heat to the thermoset coating compositions as desired provided the temperature does not reach a level that would prematurely soften and/or melt the powder coating compositions present inside the common receptacle. In other embodiments, the common receptacle has no such heating apparatus.

In certain embodiments of the methods of the present invention, the metering step comprises determining a desired amount of the thermoset powder coating composition; drawing the desired amount of the thermoset powder coating composition from the container; and dispensing the desired amount of the thermoset powder coating composition into the common receptacle.

In other embodiments, the metering step further comprises measuring a first amount of the thermoset powder coating composition dispensed into the common receptacle; comparing the first amount dispensed to the desired amount to calculate a difference between the first amount dispensed and the desired amount; using the difference between the first amount dispensed and the desired amount to calculate a second amount of the thermoset powder coating composition to be dispensed; and dispensing the second amount of the thermoset powder coating composition into the common receptacle to provide the desired amount.

The desired amount of the thermoset powder coating composition to be dispensed may be derived from a formula and/or recipe containing a list of one or more of the thermoset powder coating compositions, wherein the formula and/or recipe, as followed, results in a desired hue once the final coating film is applied to a substrate and cured. In certain embodiments, the formula and/or recipe may be stored on a computer, which may communicate with the metering system.

As mentioned, once the desired amount of the thermoset powder coating composition is determined, the desired amount is drawn from the appropriate container and subsequently dispensed into the common receptacle. In certain embodiments, the thermoset powder coating compositions may be gravimetrically dispensed from the container by weight. In other embodiments, the compositions may be volumetrically dispensed.

The metering step may be accomplished in any suitable manner that draws the thermoset powder coating composition from the container holding it and dispenses the composition from the container into the common receptacle. In certain embodiments, the metering step comprises the use of a meter mechanism. Any suitable meter mechanism may be used. Non-limiting examples include pistons, as described in U.S. Pat. No. 7,360,564, col. 4, line 47 through col. 9, line 32, the cited portion incorporated herein by reference; rotating screws as described in U.S. Pat. No. 7,134,573, col. 3, line 13 through col. 5, line 6, the cited portion incorporated herein by reference, and U.S. Pat. No. 7,311,223, col. 3, line 32 through col. 7, line 11, the cited portion incorporated herein by reference; and the like.

In certain embodiments, the meter mechanism is positioned to be able to dispense the powder coating compositions into the common receptacle. The capacity of the meter mechanism may be selectable, that is, the amount of thermoset powder coating composition to be dispensed may be varied, which may improve dispense times as well as accuracy of the amounts of dispensed compositions that may be present.

In certain embodiments, there may be a single meter mechanism which meters a controlled amount of the plurality of thermoset powder coating compositions from the plurality of containers into the common receptacle. In these embodiments, the plurality of containers and/or the single meter mechanism may be movable so that each of the plurality of containers may come in contact with the single meter mechanism as necessary to be dispensed. In other embodiments, there may be a plurality of meter mechanisms. In these embodiments, at least one meter mechanism is connected to each of the plurality of containers.

The meter mechanism may be releasably connected to a container so that it may be removed, if desired. As previously mentioned, in certain embodiments, the containers may be portable. In these embodiments, the meter mechanism is capable of detachment from and reattachment to the container as desired. As would be recognized, similar releasable properties of the meter mechanisms would be desired in embodiments where the containers are disposable and/or refillable.

In certain embodiments, the meter mechanisms may be individually controlled, that is, a meter mechanism may be controlled separately from other meter mechanisms.

In certain embodiments, the metering step comprises the use of a meter mechanism comprising at least two pump screws. In certain embodiments, the at least two pump screws present in the meter mechanism comprise one screw having a relatively large dispensing capacity and another screw having a relatively small dispensing capacity. The pump screws may be individually controlled and/or operated so that they may dispense varying amounts of the thermoset powder coating compositions. In certain embodiments, the screw having a relatively large dispensing capacity dispenses a larger amount of the thermoset powder coating composition, and the screw having a relatively small dispensing capacity dispenses a lesser amount of the thermoset powder coating composition than the screw having a relatively large capacity. In other embodiments, the screw having a relatively large dispensing capacity is larger in diameter than the screw having a relatively small dispensing capacity. In yet other embodiments, the larger screw has a diameter over twice the diameter of the small screw.

The pump screws may be made of any suitable material, including but not limited to metal, for example, stainless steel; plastic, for example, polyproplene, polytetrafluoroethylene, and the like. In certain embodiments, the meter mechanism may be operated by use of a motor.

Any suitable dispensing capacity may exist for the meter mechanism. In certain embodiments, the dispensing capacity of the meter mechanism may range from 1 milligram to 10 kilograms, such as from 1 milligram to 5,000 grams, such as from 10 milligrams to 1,000 grams, such as from 10 milligrams to 500 grams.

As mentioned, once the desired amount of the thermoset powder coating composition has been drawn from the container and dispensed into the common receptacle, a first amount that has been dispensed into the receptacle may be measured. As one would recognize, measuring of the first amount may be accomplished by any suitable measuring device including, for example, by devices that measure weight, by devices that measure volume, or other similar devices. The measuring device may be associated with the common receptacle, i.e., attached in a suitable manner, to enable rapid measurements as the powder coating compositions are dispensed. The measuring device may also be separate from the common receptacle.

Subsequently, the first amount dispensed into the receptacle may be compared to the desired amount to calculate a difference between the first amount dispensed and the desired amount. The difference between the first amount dispensed and the desired amount may then be used to calculate a second amount of the thermoset powder coating composition to be dispensed, if a second amount of the thermoset powder coating composition is necessary. As one would recognize, if the difference between the first amount dispensed and the desired amount is zero, no second amount of the thermoset powder coating composition is necessary to be dispensed. Next, the second amount of the thermoset powder coating composition may be dispensed into the common receptacle. Typically, the second amount is less than the first amount dispensed. In certain embodiments, a rotating screw having a relatively large dispensing capacity may be used to dispense the first amount, and a rotating screw having a relatively small dispensing capacity may be used to dispense the second amount.

In certain embodiments, the determination of the first and second amounts may be used to calibrate the metering mechanism for future dispenses.

The above-described method may be used to dispense any of the plurality of thermoset powder coating compositions present in the plurality of containers. In certain embodiments of the methods of the present invention, at least one of the plurality of thermoset powder coating compositions may be dispensed into a common receptacle sequentially one at a time. In other embodiments, more than one of the plurality of thermoset powder coating compositions may be dispensed simultaneously into the common receptacle as dry powder coating compositions. In certain embodiments, the plurality of thermoset powder coating compositions may be dispensed without the presence of heat and/or agitation. In other embodiments, as discussed above, agitation and/or heating of one or more of the plurality of thermoset powder coating compositions may be used, for example, while the compositions are present in the containers and/or in the common receptacle after the compositions have been dispensed.

As previously mentioned, at least one of the plurality of thermoset powder coating compositions dispensed according to the methods of the present invention comprises: (a) a colorant; (b) a particulate film-forming resin; and (c) a curing agent for the film-forming resin, and wherein each one of the thermoset powder coating compositions provides a finished decorative and durable coating when deposited onto a substrate and cured. Suitable thermoset powder coating compositions include those disclosed in U.S. Patent Application Publication No. 2006/0251891, paragraphs [0019] through [0148] and U.S. Patent Application Publication No. 2007/0172662, paragraphs [0015] through [0125], the cited portions incorporated herein by reference.

As used herein, the term “colorant” means any substance that imparts color and/or other visual effect to the composition. The colorant can be added to the thermoset powder coating composition in any suitable form, such as discrete particles, dispersions, solutions and/or flakes A single colorant or a mixture of two or more colorants can be used in the thermoset powder coating compositions of the present invention.

In certain embodiments, the powder coating compositions comprise from 0.1 to 50 percent by weight, such as 1 to 20 percent by weight, of colorant, based on the total weight of the powder coating composition.

In certain embodiments, the colorant comprises polymer-enclosed color-imparting nanoparticles. As used herein, the term “nanoparticles” refers to particles that have an average particle size of less than 1 micron. In certain embodiments, the nanoparticles used in the present invention have an average particle size of 300 nanometers or less, such as 200 nanometers or less, or, in some cases, 100 nanometers or less. It will be appreciated, of course, that a powder coating composition comprising nanoparticles may also include particles that are not nanoparticles.

For purposes of the present invention, average particle size can be measured according to known laser scattering techniques. For example, average particle size can be determined using a Horiba Model LA 900 laser diffraction particle size instrument, which uses a helium-neon laser with a wave length of 633 nm to measure the size of the particles and assumes the particle has a spherical shape, i.e., the “particle size” refers to the smallest sphere that will completely enclose the particle. Average particle size can also be determined by visually examining an electron micrograph of a transmission electron microscopy (“TEM”) image of a representative sample of the particles, measuring the diameter of the particles in the image, and calculating the average primary particle size of the measured particles based on magnification of the TEM image. One of ordinary skill in the art will understand how to prepare such a TEM image and determine the primary particle size based on the magnification. The primary particle size of a particle refers to the smallest diameter sphere that will completely enclose the particle. As used herein, the term “primary particle size” refers to the size of an individual particle.

As mentioned, in certain embodiments, the powder coating compositions comprise color-imparting nanoparticles that are polymer-enclosed and, therefore, not significantly agglomerated. As used herein, the term “polymer-enclosed nanoparticles” refers to nanoparticles that are at least partially enclosed by, i.e., confined within, a polymer to an extent sufficient to separate particles from each other within the resulting coating, such that significant agglomeration of the particles is prevented. It will be appreciated, of course, that a powder coating composition comprising such “polymer-enclosed nanoparticles” may also include nanoparticles that are not polymer-enclosed particles. As used herein, the term “color-imparting nanoparticle” refers to a particle that significantly absorbs some wavelengths of visible light, that is, wavelengths ranging from 400 to 700 nm, more than it absorbs other wavelengths in the visible region.

The shape (or morphology) of the polymer-enclosed color-imparting nanoparticles can vary. For example, generally spherical morphologies (such as solid beads, microbeads, or hollow spheres), can be used, as well as particles that are cubic, platy, or acicular (elongated or fibrous). Additionally, the particles can have an internal structure that is hollow, porous or void free, or a combination of any of the foregoing, e.g., a hollow center with porous or solid walls. For more information on suitable particle characteristics see H. Katz et al. (Ed.), Handbook of Fillers and Plastics (1987) at pages 9-10.

Depending on the desired properties and characteristics of the resultant powder coating composition (e.g., coating hardness, scratch resistance, stability, or color), mixtures of one or more polymer-enclosed color-imparting nanoparticles having different average particle sizes can be employed.

The polymer-enclosed color-imparting nanoparticles can be formed from polymeric and/or non-polymeric inorganic materials, polymeric and/or non-polymeric organic materials, composite materials, as well as mixtures of any of the foregoing. As used herein, “formed from” denotes open, e.g., “comprising,” claim language. As such, it is intended that a composition or substance “formed from” a list of recited components be a composition comprising at least these recited components, and can further comprise other, non-recited components, during the composition's formation. Additionally, as used herein, the term “polymer” is meant to encompass oligomers, and includes without limitation both homopolymers and copolymers.

As used herein, the term “polymeric inorganic material” means a polymeric material having a backbone repeat unit based on an element or elements other than carbon. Moreover, as used herein, the term “polymeric organic materials” means synthetic polymeric materials, semi-synthetic polymeric materials and natural polymeric materials, all of which have a backbone repeat unit based on carbon.

The term “organic material”, as used herein, means carbon containing compounds wherein the carbon is typically bonded to itself and to hydrogen, and often to other elements as well, and excludes binary compounds such as the carbon oxides, the carbides, carbon disulfide, etc.; such ternary compounds as the metallic cyanides, metallic carbonyls, phosgene, carbonyl sulfide, etc.; and carbon-containing ionic compounds such as metallic carbonates, for example calcium carbonate and sodium carbonate.

As used herein, the term “inorganic material” means any material that is not an organic material.

As used herein, the term “composite material” means a combination of two or more differing materials. The particles formed from composite materials generally have a hardness at their surface that is different from the hardness of the internal portions of the particle beneath its surface. More specifically, the surface of the particle can be modified in any manner well known in the art, including, but not limited to, chemically or physically changing its surface characteristics using techniques known in the art.

For example, a particle can be formed from a primary material that is coated, clad or encapsulated with one or more secondary materials to form a composite particle that has a softer surface. In certain embodiments, particles formed from composite materials can be formed from a primary material that is coated, clad or encapsulated with a different form of the primary material. For more information on particles useful in the present invention, see G. Wypych, Handbook of Fillers, 2nd Ed. (1999) at pages 15-202.

As aforementioned, the particles useful in the present invention can include any inorganic materials known in the art. Suitable particles can be formed from ceramic materials, metallic materials, and mixtures of any of the foregoing. Non-limiting examples of such ceramic materials can comprise metal oxides, mixed metal oxides, metal nitrides, metal carbides, metal sulfides, metal silicates, metal borides, metal carbonates, and mixtures of any of the foregoing. A specific, non-limiting example of a metal nitride is boron nitride; a specific, non-limiting example of a metal oxide is zinc oxide; non-limiting examples of suitable mixed metal oxides are aluminum silicates and magnesium silicates; non-limiting examples of suitable metal sulfides are molybdenum disulfide, tantalum disulfide, tungsten disulfide, and zinc sulfide; non-limiting examples of metal silicates are aluminum silicates and magnesium silicates, such as vermiculite.

In certain embodiments of the methods of the present invention, the nanoparticles of the thermoset powder coating compositions comprise inorganic materials selected from aluminum, barium, bismuth, boron, cadmium, calcium, cerium, cobalt, copper, iron, lanthanum, magnesium, manganese, molybdenum, nitrogen, oxygen, phosphorus, selenium, silicon, silver, sulfur, tin, titanium, tungsten, vanadium, yttrium, zinc, and zirconium, including oxides thereof, nitrides thereof, phosphides thereof, phosphates thereof, selenides thereof, sulfides thereof, sulfates thereof, and mixtures thereof. Suitable non-limiting examples of the foregoing inorganic particles are alumina, silica, titania, ceria, zirconia, bismuth oxide, magnesium oxide, iron oxide, aluminum silicate, boron carbide, nitrogen doped titania, and cadmium selenide.

The particles can comprise, for example, a core of essentially a single inorganic oxide, such as silica in colloidal, fumed, or amorphous form, alumina or colloidal alumina, titanium dioxide, iron oxide, cesium oxide, yttrium oxide, colloidal yttria, zirconia, e.g., colloidal or amorphous zirconia, and mixtures of any of the foregoing; or an inorganic oxide of one type upon which is deposited an organic oxide of another type.

Non-polymeric, inorganic materials useful in forming the particles used in the present invention can comprise inorganic materials selected from graphite, metals, oxides, carbides, nitrides, borides, sulfides, silicates, carbonates, sulfates, and hydroxides. A non-limiting example of a useful inorganic oxide is zinc oxide. Non-limiting examples of suitable inorganic sulfides include molybdenum disulfide, tantalum disulfide, tungsten disulfide, and zinc sulfide. Non-limiting examples of useful inorganic silicates include aluminum silicates and magnesium silicates, such as vermiculite. Non-limiting examples of suitable metals include molybdenum, platinum, palladium, nickel, aluminum, copper, gold, iron, silver, alloys, and mixtures of any of the foregoing.

In certain embodiments, the particles can be selected from fumed silica, amorphous silica, colloidal silica, alumina, colloidal alumina, titanium dioxide, iron oxide, cesium oxide, yttrium oxide, colloidal yttria, zirconia, colloidal zirconia, and mixtures of any of the foregoing. In certain embodiments, the particles comprise colloidal silica. As disclosed above, these materials can be surface treated or untreated. Other useful particles include surface-modified silicas, such as are described in U.S. Pat. No. 5,853,809 at column 6, line 51 to column 8, line 43, incorporated herein by reference.

As another alternative, a particle can be formed from a primary material that is coated, clad or encapsulated with one or more secondary materials to form a composite material that has a harder surface. Alternatively, a particle can be formed from a primary material that is coated, clad or encapsulated with a differing form of the primary material to form a composite material that has a harder surface.

In one example, and without limiting the present invention, an inorganic particle formed from an inorganic material, such as silicon carbide or aluminum nitride, can be provided with a silica, carbonate or nanoclay coating to form a useful composite particle. In another non-limiting example, a silane coupling agent with alkyl side chains can interact with the surface of an inorganic particle formed from an inorganic oxide to provide a useful composite particle having a “softer” surface. Other examples include cladding, encapsulating or coating particles formed from non-polymeric or polymeric materials with differing non-polymeric or polymeric materials. A specific non-limiting example of such composite particles is a synthetic polymeric particle coated with calcium carbonate that is commercially available under the tradename DUALITE particles from Pierce and Stevens Corporation of Buffalo, N.Y.

In certain embodiments, the particles used in the present invention have a lamellar structure. Particles having a lamellar structure are composed of sheets or plates of atoms in hexagonal array, with strong bonding within the sheet and weak van der Waals bonding between sheets, providing low shear strength between sheets. A non-limiting example of a lamellar structure is a hexagonal crystal structure. Inorganic solid particles having a lamellar fullerene (i.e., buckyball) structure are also useful in the present invention.

Non-limiting examples of suitable materials having a lamellar structure include boron nitride, graphite, metal dichalcogenides, mica, talc, gypsum, kaolinite, calcite, cadmium iodide, silver sulfide, and mixtures thereof. Suitable metal dichalcogenides include molybdenum disulfide, molybdenum diselenide, tantalum disulfide, tantalum diselenide, tungsten disulfide, tungsten diselenide, and mixtures thereof.

The particles can be formed from non-polymeric, organic materials. Non-limiting examples of non-polymeric, organic materials useful in the present invention include, but are not limited to, stearates (such as zinc stearate and aluminum stearate), diamond, carbon black, and stearamide.

The particles used in the present invention can be formed from inorganic polymeric materials. Non-limiting examples of useful inorganic polymeric materials include polyphosphazenes, polysilanes, polysiloxanes, polygernanes, polymeric sulfur, polymeric selenium, silicones, and mixtures of any of the foregoing. A specific, non-limiting example of a particle formed from an inorganic polymeric material suitable for use in the present invention is Tospearl, which is a particle formed from cross-linked siloxanes and is commercially available from Toshiba Silicones Company, Ltd. of Japan.

The particles can be formed from synthetic, organic polymeric materials. Non-limiting examples of suitable organic polymeric materials include, but are not limited to, thermoset materials and thermoplastic materials. Non-limiting examples of suitable thermoplastic materials include thermoplastic polyesters, such as polyethylene terephthalate, polybutylene terephthalate and polyethylene naphthalate, polycarbonates, polyolefins, such as polyethylene, polypropylene and polyisobutene, acrylic polymers, such as copolymers of styrene and an acrylic acid monomer and polymers containing methacrylate, polyamides, thermoplastic polyurethanes, vinyl polymers, and mixtures of any of the foregoing.

Non-limiting examples of suitable thermoset materials include thermoset polyesters, vinyl esters, epoxy materials, phenolics, aminoplasts, thermoset polyurethanes and mixtures of any of the foregoing. A specific, non-limiting example of a synthetic polymeric particle formed from an epoxy material is an epoxy microgel particle.

The particles can also be hollow particles formed from materials selected from polymeric and non-polymeric inorganic materials, polymeric and non-polymeric organic materials, composite materials, and mixtures of any of the foregoing. Non-limiting examples of suitable materials from which the hollow particles can be formed are described above.

In certain embodiments, the nanoparticles used in the present invention comprise an organic pigment, for example, azo compounds (monoazo, di-azo, .beta.-Naphthol, Naphthol AS salt type azo pigment lakes, benzimidazolone, di-azo condensation, isoindolinone, isoindoline), and polycyclic (phthalocyanine, quinacridone, perylene, perinone, diketopyrrolo pyrrole, thioindigo, anthraquinone, indanthrone, anthrapyrimidine, flavanthrone, pyranthrone, anthanthrone, dioxazine, triarylcarbonium, quinophthalone) pigments, and mixtures of any of the foregoing. In certain embodiments, the organic material is selected from perylenes, quinacridones, phthalocyanines, isoindolines, dioxazines (that is, triphenedioxazines), 1,4-diketopyrrolopyrroles, anthrapyrimidines, anthanthrones, flavanthrones, indanthrones, perinones, pyranthrones, thioindigos, 4,4′-diamino-1,1′-dianthraquinonyl, as well as substituted derivatives thereof, and mixtures thereof.

Perylene pigments used in the practice of the present invention may be unsubstituted or substituted. Substituted perylenes may be substituted at imide nitrogen atoms for example, and substituents may include an alkyl group of 1 to 10 carbon atoms, an alkoxy group of 1 to 10 carbon atoms and a halogen (such as chlorine) or combinations thereof. Substituted perylenes may contain more than one of any one substituent. The diimides and dianhydrides of perylene-3,4,9,10-tetracarboxylic acid are preferred. Crude perylenes can be prepared by methods known in the art.

Phthalocyanine pigments, especially metal phthalocyanines may be used. Although copper phthalocyanines are more readily available, other metal-containing phthalocyanine pigments, such as those based on zinc, cobalt, iron, nickel, and other such metals, may also be used. Metal-free phthalocyanines are also suitable. Phthalocyanine pigments may be unsubstituted or partially substituted, for example, with one or more alkyl (having 1 to 10 carbon atoms), alkoxy (having 1 to 10 carbon atoms), halogens such as chlorine, or other substituents typical of phthalocyanine pigments. Phthalocyanines may be prepared by any of several methods known in the art. They are typically prepared by a reaction of phthalic anhydride, phthalonitrile, or derivatives thereof, with a metal donor, a nitrogen donor (such as urea or the phthalonitrile itself), and an optional catalyst, preferably in an organic solvent.

Quinacridone pigments, as used herein, include unsubstituted or substituted quinacridones (for example, with one or more alkyl, alkoxy, halogens such as chlorine, or other substituents typical of quinacridone pigments), and are suitable for the practice of the present invention. The quinacridone pigments may be prepared by any of several methods known in the art but are preferably prepared by thermally ring-closing various 2,5-dianilinoterephthalic acid precursors in the presence of polyphosphoric acid.

Isoindoline pigments, which can optionally be substituted symmetrically or unsymmetrically, are also suitable for the practice of the present invention can be prepared by methods known in the art. A suitable isoindoline pigment, Pigment Yellow 139, is a symmetrical adduct of iminoisoindoline and barbituric acid precursors. Dioxazine pigments (that is, triphenedioxazines) are also suitable organic pigments and can be prepared by methods known in the art.

Mixtures of any of the previously described inorganic particles and/or organic particles can also be used.

As mentioned, the thermoset powder coating compositions used in certain embodiments of the methods of the present invention comprise polymer-enclosed color-imparting nanoparticles. In certain embodiments, the nanoparticles are formed in situ during formation of an aqueous dispersion of polymer-enclosed particles, as described in more detail below. In other embodiments, however, the nanoparticles are formed prior to their incorporation into such an aqueous dispersion. In these embodiments, the nanoparticles can be formed by any of a number of various methods known in the art. For example, the nanoparticles can be prepared by pulverizing and classifying the dry particulate material. For example, bulk particles such as any of the inorganic or organic particles discussed above, can be milled with milling media having a particle size of less than 0.5 millimeters (mm), or less than 0.3 mm, or less than 0.1 mm. The particles typically are milled to nanoparticle sizes in a high energy mill in one or more solvents (either water, organic solvent, or a mixture of the two), optionally in the presence of a polymeric grind vehicle. If necessary, a dispersant can be included, for example, (if in organic solvent) SOLSPERSE 32000 or 32500 dispersant available from Lubrizol Corporation, or (if in water) SOLSPERSE 27000 dispersant, also available from Lubrizol Corporation. Other suitable methods for producing the nanoparticles include crystallization, precipitation, gas phase condensation, and chemical attrition (i.e., partial dissolution).

In certain embodiments, the polymer-enclosed color-imparting nanoparticles are formed from an aqueous dispersion of polymer-enclosed color-imparting nanoparticles. As used herein, the term “dispersion” refers to a two-phase system in which one phase includes finely divided particles distributed throughout a second phase, which is a continuous phase. The dispersions often are oil-in-water emulsions, wherein an aqueous medium provides the continuous phase of the dispersion in which the polymer-enclosed particles are suspended as the organic phase.

As used herein, the term “aqueous”, “aqueous phase”, “aqueous medium,” and the like, refers to a medium that either consists exclusively of water or comprises predominantly water in combination with another material, such as, for example, an inert organic solvent. In certain embodiments, the amount of organic solvent present in the aqueous dispersions is less than 20 weight percent, such as less than 10 weight percent, or, in some cases, less than 5 weight percent, or, in yet other cases, less than 2 weight percent, with the weight percents being based on the total weight of the dispersion. Non-limiting examples of suitable organic solvents are propylene glycol monobutyl ether, ethylene glycol monohexyl ether, ethylene glycol monobutyl ether, n-butanol, benzyl alcohol, and mineral spirits.

The polymer-enclosed color-imparting nanoparticles used in the present invention may comprise, for example, a polymer selected from acrylic polymers, polyurethane polymers, polyester polymers, polyether polymers, silicon-based polymers, co-polymers thereof, and mixtures thereof. Such polymers can be produced by any suitable method known to those skilled in the art to which the present invention pertains. Suitable polymer include those disclosed in U.S. patent application Ser. No. 10/876,031 at [0061] to [0076], the cited portion of which being incorporated by reference herein, and U.S. Patent Application Publication No. 2005/0287348 A1 at [0042] to [0044], the cited portion of which being incorporation by reference herein.

In certain embodiments, such aqueous dispersions comprise color-imparting nanoparticles enclosed by a friable polymer. As used herein, the term “friable polymer” refers to a polymer that is easily pulverized at ambient conditions. That is, upon removal of liquid materials from the dispersion, the resulting solid material does not coalesce and is easily broken into small fragments or pieces, such as would be suitable as a dry feed material to an extruder to produce a powder coating composition. A film-forming polymer, on the other hand, would, upon removal of liquid materials from the dispersion, form a self-supporting continuous film on at least a horizontal surface of a substrate. As used herein, the term “ambient conditions” refers to surrounding conditions, which is often around one atmosphere of pressure, 50% relative humidity, and 25° C.

In certain embodiments, the friable polymer comprises the reaction product of (i) a polymerizable polyester polyurethane, and (ii) an ethylenically unsaturated monomer. As used herein, the term “polymerizable polyester polyurethane” refers to a polymer that includes a plurality of ester units,

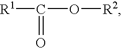

and a plurality of urethane units

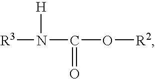

has functional groups that are capable of being polymerized to form a larger polymer, and wherein R¹ is an alkyl, cycloalkyl or oxyalkyl moiety, R² is an alkyl or cycloalkyl moiety, and R³ is alkyl, cycloalkyl, arakyl, or aromatic moiety. In certain embodiments, the polymerizable polyester polyurethane comprises a polyester polyurethane having terminal ethylenic unsaturation. As used herein, the phrase “terminal ethylenic unsaturation” means that at least some of the terminal ends of the polyester polyurethane contain a functional group containing ethylenic unsaturation. Such polyester polyurethanes may also include, but need not necessarily include, internal ethylenic unsaturation. As a result, in certain embodiments, the aqueous dispersion comprises a polymerizable polyester polyurethane having terminal ethylenic unsaturation which is prepared from reactants comprising (a) a polyisocyanate, (b) a polyester polyol, and (c) a material comprising an ethylenically unsaturated group and an active hydrogen group. In certain embodiments, the polymerizable polyester polyurethane is formed from reactants further comprising (d) a polyamine, and/or (e) a material comprising an acid functional group or anhydride and a functional group reactive with isocyanate or hydroxyl groups. As used herein, the term “active-hydrogen group” refers to functional groups that are reactive with isocyanates as determined by the Zerewitnoff test as described in the JOURNAL OF THE AMERICAN CHEMICAL SOCIETY, Vol. 49, page 3181 (1927).

Polyisocyanates suitable for use in preparing the polymerizable polyester polyurethane include aliphatical, cycloaliphatical, araliphatical, and/or aromatic isocyanates, and mixtures thereof.

Examples of useful aliphatic and cycloaliphatic polyisocyanates include 4,4-methylenebisdicyclohexyl diisocyanate (hydrogenated MDI), hexamethylene diisocyanate (HDI), isophorone diisocyanate (IPDI), methylenebis(cyclohexyl isocyanate), trimethyl hexamethylene diisocyanate (TMDI), meta-tetramethylxylylene diisocyanate (TMXDI), and cyclohexylene diisocyanate (hydrogenated XDI). Other aliphatic polyisocyanates include isocyanurates of IPDI and HDI.

Examples of suitable aromatic polyisocyanates include tolylene diisocyanate (TDI) (i.e., 2,4-tolylene diisocyanate, 2,6-tolylene diisocyanate or a mixture thereof), diphenylmethane-4,4-diisocyanate (MDI), naphthalene-1,5-diisocyanate (NDI), 3,3-dimethyl-4,4-biphenylene diisocyanate (TODI), crude TDI (i.e., a mixture of TDI and an oligomer thereof), polymethylenepolyphenyl polyisocyanate, crude MDI (i.e., a mixture of MDI and an oligomer thereof), xylylene diisocyanate (XDI), and phenylene diisocyanate.

Polyisocyanate derivatives prepared from hexamethylene diisocyanate, 1-isocyanato-3,3,5-trimethyl-5-isocyanatomethylcyclohexane (“IPDI”), including isocyanurates thereof, and/or 4,4′-bis(isocyanatocyclohexyl)methane are suitable.

In certain embodiments, the amount of polyisocyanate used to prepare the polymerizable polyester polyurethane ranges from 20 to 70 percent by weight, such as 30 to 60 percent by weight or, in some cases, 40 to 50 percent by weight, with the weight percents being based on the total weight of resin solids used to prepare the polymerizable polyester polyurethane.

Polyester polyols suitable for use in preparing the polymerizable polyester polyurethane may be prepared by any suitable method, e.g., using saturated dicarboxylic acids or anhydrides thereof (or combination of acids and anhydrides) and polyhydric alcohols, or by ring opening of caprolactones, e.g., epsilon caprolactone. Such polyester polyols are commercially available in various molecular weights. Aliphatic dicarboxylic acids suitable for preparing polyesters include those containing from 4 to 14, such as 6 to 10, carbon atoms inclusive. Examples of such dicarboxylic acids include: succinic acid, glutaric acid, adipic acid, pimelic acid, suberic acid, azelaic aid, and sebacic acid. Corresponding anhydrides can also be used. Typically, adipic and azelaic acids are used.

Polyhydric alcohols used in the preparation of polyester polyols suitable for use in preparing the polymerizable polyester polyurethane include, without limitation, aliphatic alcohols containing at least 2 hydroxy groups, e.g., straight chain glycols containing from 2 to 15, such as 4 to 8, carbon atoms inclusive. In certain embodiments, the glycols contain hydroxyl groups in the terminal positions. Non-limiting examples of such polyhydric alcohols include ethylene glycol, diethylene glycol, triethylene glycol, tetraethylene glycol, 1,3-propane diol, 1,3-butane diol, 1,4-butane diol, 1,5-pentane diol, 2,2-dimethylpropane diol, 1,5-hexane diol, 1,7-heptane diol, 1,8-octane diol, 1,10-decane diol, and mixtures of such polyhydric alcohols.

In certain embodiments, the polyester polyol is prepared by reacting a dicarboxylic acid (or anhydride thereof) with a polyhydric alcohol in the presence of an esterification catalyst, such as an organo tin catalyst. The amount of acid and alcohol used will vary and depend on the molecular weight polyester desired. Hydroxy terminated polyesters are obtained by utilizing an excess of the alcohol, thereby to obtain linear chains containing a preponderance of terminal hydroxyl groups. Examples of polyesters include: poly(1,4-butylene adipate), poly(1,4-butylene succinate), poly(1,4-butylene glutarate), poly(1,4-butylene pimelate), poly(1,4-butylene suberate), poly(1,4-butylene azelate), poly(1,4butylene sebacate), and poly(epsilon caprolactone). In certain embodiments, the polyester polyol utilized in preparing the friable, polymerizable polyester polyurethane has a weight average molecular weight from 500 to 3000, such as 500 to 2500, or, in some cases, 900 to about 1300.

In certain embodiments, the amount of polyester polyol used to prepare the polymerizable polyester polyurethane included in certain embodiments of the present invention ranges from 10 to 60 percent by weight, such as 20 to 50 percent by weight or, in some cases, 30 to 40 percent by weight, with the weight percents being based on the total weight of resin solids used to prepare the polymerizable polyester polyurethane.

As indicated, the polymerizable polyester polyurethane present in certain embodiments of the present invention is formed from a material comprising an ethylenically unsaturated group and an active hydrogen group. Suitable ethylenically unsaturated groups include, for example, acrylates, methacrylates, allyl carbamates, and allyl carbonates. The acrylate and methacrylate functional groups may be represented by the formula, CH₂═C(R₁)—C(O)O—, wherein R₁ is hydrogen or methyl. The allyl carbamates and carbonates may be represented by the formulae, CH₂═CH—CH₂—NH—C(O)O—, and CH₂═CH—CH₂—O—(O)O—, respectively.

In certain embodiments, the material comprising an ethylenically unsaturated group and an active hydrogen group utilized in preparing the polymerizable polyester polyurethane comprises a hydroxyalkyl(meth)acrylate. Suitable hydroxyalkyl(meth)acrylates include those having from 1 to 18 carbon atoms in the alkyl radical, the alkyl radical being substituted or unsubstituted. Specific non-limiting examples of such materials include 2-hydroxyethyl(meth)acrylate, 2-hydroxypropyl(meth)acrylate, 2-hydroxybutyl(meth)acrylate, hexane-1,6-diol mono(meth)acrylate, 4-hydroxybutyl(meth)acrylate, and mixtures thereof. As used herein, the term “(meth)acrylate” is meant to include both acrylates and methacrylates.

In certain embodiments, the amount of the material comprising an ethylenically unsaturated group and an active hydrogen group used to prepare the polymerizable polyester polyurethane ranges from 1 to 12 percent by weight, such as 2 to 8 percent by weight or, in some cases, 4 to 6 percent by weight, with the weight percents being based on the total weight of resin solids used to prepare the polymerizable polyester polyurethane.

As previously indicated, in certain embodiments, the polymerizable polyester polyurethane is formed from a polyamine. Useful polyamines include, but are not limited to, primary or secondary diamines or polyamines in which the groups attached to the nitrogen atoms can be saturated or unsaturated, aliphatic, alicyclic, aromatic, aromatic-substituted-aliphatic, aliphatic-substituted-aromatic, and heterocyclic. Exemplary suitable aliphatic and alicyclic diamines include 1,2-ethylene diamine, 1,2-porphylene diamine, 1,8-octane diamine, isophorone diamine, propane-2,2-cyclohexyl amine, and the like. Exemplary suitable aromatic diamines include phenylene diamines and the toluene diamines, for example, o-phenylene diamine and p-tolylene diamine. These and other suitable polyamines are described in detail in U.S. Pat. No. 4,046,729 at column 6, line 61 to column 7, line 26, the cited portion of which being incorporated herein by reference.

In certain embodiments, the amount of polyamine used to prepare the polymerizable polyester polyurethane ranges from 0.5 to 5 percent by weight, such as 1 to 4 percent by weight or, in some cases, 2 to 3 percent by weight, with the weight percents being based on the total weight of resin solids used to prepare the polymerizable polyester polyurethane.

As previously indicated, in certain embodiments, the polymerizable polyester polyurethane is formed from a material comprising an acid functional group or anhydride and a functional group reactive with the isocyanate or hydroxyl groups of other components from which the polyurethane material is formed. Useful acid functional materials include compounds having the structure:

X—Y-Z

wherein X is OH, SH, NH₂, or NHR, and R includes alkyl, aryl, cycloalkyl, substituted alkyl, substituted aryl, and substituted cycloalkyl groups, and mixtures thereof; Y includes alkyl, aryl, cycloalkyl, substituted alkyl, substituted aryl, and substituted cycloalkyl groups, and mixtures thereof; and Z includes OSO₃H, COOH, OPO₃H₂, SO₂OH, POOH, and PO₃H₂, and mixtures thereof.

Examples of suitable acid functional materials include hydroxypivalic acid, 3-hydroxy butyric acid, D,L-tropic acid, D,L hydroxy malonic acid, D,L-malic acid, citric acid, thioglycolic acid, glycolic acid, amino acid, 12-hydroxy stearic acid, dimethylol propionic acid, mercapto propionic acid, mercapto butyric acid, mercapto-succinic acid, and mixtures thereof.

Useful anhydrides include aliphatic, cycloaliphatic, olefinic, cycloolefinic and aromatic anhydrides. Substituted aliphatic and aromatic anhydrides also are useful provided the substituents do not adversely affect the reactivity of the anhydride or the properties of the resultant polyurethane. Examples of substituents include chloro, alkyl, and alkoxy. Examples of anhydrides include succinic anhydride, methylsuccinic anhydride, dodecenyl succinic anhydride, octadecenylsuccinic anhydride, phthalic anhydride, tetrahydrophthalic anhydride, methyltetrahydrophthalic anhydride, hexahydrophthalic anhydride, alkyl hexahydrophthalic anhydrides such as methylhexahydrophthalic anhydride, tetrachlorophthalic anhydride, endomethylene tetrahydrophthalic anhydride, trimellitic anhydride, chlorendic anhydride, itaconic anhydride, citraconic anhydride, maleic anhydride, and mixtures thereof.

In certain embodiments, the acid functional material or anhydride provides the polymerizable polyester polyurethane with anionic ionizable groups which can be ionized for solubilizing the polymer in water. As a result, in certain embodiments, the polymerizable polyester polyurethane is water-dispersible. As used herein, the term “water-dispersible” means that a material may be dispersed in water without the aid or use of a surfactant. As used herein, the term “ionizable” means a group capable of becoming ionic, i.e., capable of dissociating into ions or becoming electrically charged. An acid may be neutralized with base to from a carboxylate salt group. Examples of anionic groups include —OSO₃⁻, —COO⁻, —OPO₃⁻, —SO₂O, —POO⁻, and PO₃⁼.

In certain embodiments, the amount of the material comprising an acid functional group or anhydride and a functional group reactive with isocyanate or hydroxyl groups used to prepare the polymerizable polyester polyurethane ranges from 5 to 20 percent by weight, such as 7 to 15 percent by weight or, in some cases, 8 to 12 percent by weight, with the weight percents being based on the total weight of resin solids used to prepare the polymerizable polyester polyurethane.

As indicated, in certain embodiments, the acid groups are neutralized with a base. Neutralization can range from 0.6 to 1.1, such as 0.4 to 0.9, or, in some cases, 0.8 to 1.0, of the total theoretical neutralization equivalent. Suitable neutralizing agents include inorganic and organic bases such as sodium hydroxide, potassium hydroxide, ammonia, amines, alcohol amines having at least one primary, secondary, or tertiary amino group and at least one hydroxyl group. Suitable amines include alkanolamines, such as monoethanolamine, diethanolamine, dimethylaminoethanol, diisopropanolamine, and the like.

The polymerizable polyester polyurethane present in certain embodiments of the present invention may be formed by combining the above-identified components in any suitable arrangement. For example, the polymerizable polyester polyurethane may be prepared by solution polymerization techniques understood by those skilled in the art to which the present invention pertains.

As should be apparent from the foregoing description, the polymerizable polyester polyurethane can be nonionic, anionic, or cationic. In certain embodiments, the polymerizable polyester polyurethane will have a weight average molecular weight of less than 150,000 grams per mole, such as from 10,000 to 100,000 grams per mole, or, in some cases, from 40,000 to 80,000 grams per mole. The molecular weight of the polyurethane and any other polymeric materials described herein is determined by gel permeation chromatography using a polystyrene standard.

As previously indicated, in certain embodiments of the present invention, a friable polymer is present that comprises the reaction product of (i) a polymerizable polyester polyurethane, such as that previously described, and (ii) an ethylenically unsaturated monomer. Suitable ethylenically unsaturated monomers include any of the polymerizable ethylenically, unsaturated monomers, including vinyl monomers known in the art. Non-limiting examples of useful ethylenically unsaturated carboxylic acid functional group-containing monomers include (meth)acrylic acid, beta-carboxyethyl acrylate, acryloxypropionic acid, crotonic acid, fumaric acid, monoalkyl esters of fumaric acid, maleic acid, monoalkyl esters of maleic acid, itaconic acid, monoalkyl esters of itaconic acid and mixtures thereof. As used herein, “(meth)acrylic” and terms derived therefrom are intended to include both acrylic and methacrylic.

Non-limiting examples of other useful ethylenically unsaturated monomers free of carboxylic acid functional groups include alkyl esters of (meth)acrylic acids, for example, ethyl(meth)acrylate, methyl(meth)acrylate, butyl(meth)acrylate, 2-ethylhexyl(meth)acrylate, 2-hydroxyethyl(meth)acrylate, hydroxypropyl(meth)acrylate, hydroxy butyl(meth)acrylate, isobornyl(meth)acrylate, lauryl(meth)acrylate, and ethylene glycol di(meth)acrylate; vinyl aromatics such as styrene and vinyl toluene; (meth)acrylamides such as N-butoxymethyl acrylamide; acrylonitriles; dialkyl esters of maleic and fumaric acids; vinyl and vinylidene halides; vinyl acetate; vinyl ethers; allyl ethers; allyl alcohols; derivatives thereof and mixtures thereof.

The ethylenically unsaturated monomers also can include ethylenically unsaturated, beta-hydroxy ester functional monomers, such as those derived from the reaction of an ethylenically unsaturated acid functional monomer, such as a monocarboxylic acid, for example, acrylic acid, and an epoxy compound which does not participate in the free radical initiated polymerization with the unsaturated acid monomer. Examples of such epoxy compounds are glycidyl ethers and esters. Suitable glycidyl ethers include glycidyl ethers of alcohols and phenols such as butyl glycidyl ether, octyl glycidyl ether, phenyl glycidyl ether, and the like.

In certain embodiments, the polymerizable polyester polyurethane and the ethylenically unsaturated monomer are present in the aqueous dispersion in a weight ratio of 95:5 to 30:70, such as 90:10 to 40:60, or, in some cases, from 80:20 to 60:40.

The aqueous dispersions described herein can be prepared by any of a variety of methods. For example, in certain embodiments, the aqueous dispersion is prepared by a method comprising (A) providing a mixture, in an aqueous medium, of (i) color-imparting nanoparticles, (ii) one or more polymerizable, ethylenically unsaturated monomers; and/or (iii) a mixture of one or more polymerizable unsaturated monomers with one or more polymers; and/or (iv) one or more polymers, and then subjecting the mixture to high stress shear conditions in the presence of an aqueous medium. Such methods are described in detail in U.S. patent application Ser. No. 10/876,031 at [0054] to [0090], the cited portion of which being incorporated by reference herein, and U.S. Patent Application Publication No. 2005/0287348 A1 at [0036] to [0050], the cited portion of which being incorporation by reference herein.

In certain embodiments, however, the aqueous dispersions are made by a method comprising (1) providing a mixture, in an aqueous medium, of (i) color-imparting particles, (ii) a polymerizable ethylenically unsaturated monomer, and (iii) a water-dispersible polymerizable dispersant, and (2) polymerizing the ethylenically unsaturated monomer and polymerizable dispersant to form polymer-enclosed color-imparting nanoparticles comprising a water-dispersible polymer. In these embodiments, the polymerizable dispersant may comprise any polymerizable material that is water-dispersible and which, upon polymerization with the ethylenically unsaturated monomer, produces polymer-enclosed color-imparting nanoparticles comprising a water-dispersible polymer, in some cases, a water-dispersible, friable polymer. In certain embodiments, the polymerizable dispersant comprises the previously described water-dispersible, polymerizable polyester polyurethane having terminal ethylenic unsaturation.

In these embodiments, the water-dispersible polymerizable dispersant is capable of dispersing itself and other materials, including the ethylenically unsaturated monomers, in the aqueous medium without the need for surfactants and/or high shear conditions. As a result, the foregoing method for making an aqueous dispersion of polymer-enclosed color-imparting nanoparticles is particularly suitable in situations where use of the high stress shear conditions described in U.S. patent application Ser. No. 10/876,031, at [0081] to [0084] and U.S. Patent Application Publication No. 2005/0287348 A1 at [0046] is not desired or feasible. Therefore, in certain embodiments, the aqueous dispersion of polymer-enclosed color-imparting nanoparticles is prepared by a method that does not include the step of subjecting the mixture of color-imparting nanoparticles, polymerizable ethylenically unsaturated monomer, and water-dispersible polymerizable dispersant to high stress shear conditions.

In addition, the foregoing method enables the formation of nanoparticles in situ, rather than requiring their formation prior to the preparation of the aqueous dispersion. In these methods, particles having a primary particle size of 1 micron or more, after being mixed with the ethylenically unsaturated monomer and the water-dispersible polymerizable dispersant in the aqueous medium, may be formed into color-imparting nanoparticles (i.e., the nanoparticles are formed in situ). In certain embodiments, the color-imparting nanoparticles are formed by subjecting the aqueous medium to pulverizing conditions. For example, the particles can be milled with milling media having a particle size of less than 0.5 millimeters, or less than 0.3 millimeters, or, in some cases, less than 0.1 millimeters. In these embodiments, the color-imparting particles can be milled to nanoparticle size in a high energy mill in the presence of the aqueous medium, the polymerizable ethylenically unsaturated monomer, and the water-dispersible polymerizable dispersant. If desired, another dispersant can be used, such as SOLSPERSE 27000 dispersant, available from Avecia, Inc.

As indicated, the foregoing methods for making aqueous dispersions of polymer-enclosed color-imparting nanoparticles include the step of polymerizing the ethylenically unsaturated monomer and polymerizable dispersant to form polymer-enclosed color-imparting nanoparticles comprising a water-dispersible polymer. In certain embodiments, at least a portion of the polymerization occurs during formation of nanoparticles, if applicable. Also, a free radical initiator may be used. Both water and oil soluble initiators can be used.

Non-limiting examples of suitable water-soluble initiators include ammonium peroxydisulfate, potassium peroxydisulfate, and hydrogen peroxide. Non-limiting examples of oil soluble initiators include t-butyl hydroperoxide, dilauryl peroxide and 2,2′-azobis(isobutyronitrile). In many cases, the reaction is carried out at a temperature ranging from 20° C. to 80° C. The polymerization can be carried out in either a batch or a continuous process. The length of time necessary to carry out the polymerization can range from, for example, 10 minutes to 6 hours, provided that the time is sufficient to form a polymer in situ from the one or more ethylenically unsaturated monomers.

Once the polymerization process is complete, the resultant product is a stable dispersion of polymer-enclosed color-imparting nanoparticles in an aqueous medium which can contain some organic solvent. Some or all of the organic solvent can be removed via reduced pressure distillation at a temperature, for example, of less than 40° C. As used herein, the term “stable dispersion” or “stably dispersed” means that the polymer-enclosed color-imparting nanoparticles neither settle nor coagulate nor flocculate from the aqueous medium upon standing.

In certain embodiments, the polymer-enclosed nanoparticles are present in the aqueous dispersions in an amount of at least 10 weight percent, or in an amount of 10 to 80 weight percent, or in an amount of 25 to 50 weight percent, or in an amount of 25 to 40 weight percent, with weight percents being based on weight of total solids present in the dispersion.

In certain embodiments, the dispersed polymer-enclosed nanoparticles have a maximum haze of 10%, or, in some cases, a maximum haze of 5%, or, in yet other cases, a maximum haze of 1%, or, in other embodiments, a maximum haze of 0.5%. As used herein, “haze” is determined by ASTM D1003.

The haze values for the polymer-enclosed nanoparticles described herein are determined by first having the nanoparticles, dispersed in a liquid (such as water, organic solvent, and/or a dispersant, as described herein) and then measuring these dispersions diluted in a solvent, for example, butyl acetate, using a Byk-Gardner TCS (The Color Sphere) instrument having a 500 micron cell path length. Because the % haze of a liquid sample is concentration dependent, the % haze as used herein is reported at a transmittance of about 15% to about 20% at the wavelength of maximum absorbance. An acceptable haze may be achieved for relatively large particles when the difference in refractive index between the particles and the surrounding medium is low. Conversely, for smaller particles, greater refractive index differences between the particle and the surrounding medium may provide an acceptable haze.

In certain embodiments, particularly wherein the polymer-enclosed nanoparticles comprise a friable polymer, the aqueous dispersion of polymer-enclosed color-imparting nanoparticles may then be further processed by (1) removing water from the aqueous dispersion to form a solid material comprising the polymer-enclosed color-imparting nanoparticles, and (2) fragmenting the solid material. In these embodiments, the water can be removed from the aqueous dispersion by any suitable drying method, such as through the use of a drum dryer, a roller dryer, a spray dryer, or the like. Moreover, the solid material can be fragmented by any suitable technique, such as through the use of a hammer mill or the like. Following fragmentation, the resultant granules may be further processed, such as by being screened in a classifier, before packaging.

In the thermoset powder coating compositions of the methods of the present invention, the polymer-enclosed color-imparting nanoparticles are incorporated into a powder coating composition. In certain embodiments, such powder coating compositions comprise from 0.1 to 50 percent by weight, such as 1 to 20 percent by weight, of polymer-enclosed nanoparticles, based on the total weight of the powder coating composition.

As mentioned, in addition to the colorant, the thermoset powder coating composition comprises a particulate film-forming resin. Suitable film-forming resins include, for example, an epoxy resin, such as an epoxy group-containing acrylic polymer or a polyglycidyl ether of a polyhydric alcohol and a suitable curing agent for the epoxy resin, such as a polyfunctional carboxylic acid group-containing material or a dicyanamide. Examples of curable particulate resinous materials are described in U.S. Pat. No. RE 32,261 and U.S. Pat. No. 4,804,581, incorporated by reference herein. Examples of other suitable particulate film-forming resins are carboxylic acid functional resins, such as carboxylic acid functional polyesters and acrylic polymers and suitable curing agents for such materials, such as triglycidyl isocyanurate and beta-hydroxyalkylamide curing agents as described, for example, in U.S. Pat. No. 4,801,680 and U.S. Pat. No. 4,988,767, incorporated by reference herein.

In certain embodiments, such powder coating compositions comprise from 50 to 90 percent by weight, such as 60 to 80 percent by weight, of the particulate film-forming resin, based on the total weight of the powder coating composition.

As mentioned, the thermoset powder coating composition comprises a curing agent for the film-forming resin. Suitable curing agents include, without limitation, blocked isocyanates, uretidiones, polyepoxides, polyacids, polyols, anhydrides, polyamines, aminoplasts and phenoplasts. As previously indicated, the appropriate curing agent can be selected by one skilled in the art depending on the polymer used. For example, blocked isocyanates are suitable curing agents for hydroxy and primary and/or secondary amino group containing materials. Examples of blocked isocyanates are those described in U.S. Pat. No. 4,988,793, at col. 3, lines 1-36, the cited portion of which being incorporated by reference herein. Polyepoxides suitable for use as curing agents for COOH functional group-containing materials are described in U.S. Pat. No. 4,681,811 at col. 5, lines 33-58, the cited portion of which being incorporated by reference herein. Polyacids as curing agents for epoxy functional group-containing materials are described in U.S. Pat. No. 4,681,811 at col. 6, line 45 to col. 9, line 54, the cited portion of which being incorporated by reference herein. Polyols, materials having an average of 2 or more hydroxyl groups per molecule, can be used as curing agents for NCO functional group-containing materials and anhydrides, and are well known in the art. Polyols for use in the present invention are typically selected such that the resultant material has a Tg greater than about 30° C., in some cases greater than 50° C. Anhydrides as curing agents for epoxy functional group-containing materials include, for example, trimellitic anhydride, benzophenone tetracarboxylic dianhydride, pyrrolmellitic dianhydride, tetrahydrophthalic anhydride, and the like as described in U.S. Pat. No. 5,472,649 at col. 4, lines 49-52, the cited portion of which being incorporated by reference herein. Aminoplasts as curing agents for hydroxy, COOH, and carbamate functional group-containing materials are well known in the art. Examples of such curing agents include aldehyde condensates of glycol urea, which give high melting crystalline products useful in powder coatings. While the aldehyde used is typically formaldehyde, other aldehydes such as acid aldehyde, crotonaldehyde, and benzaldehyde can be used. In certain embodiments, the curing agent is present in an amount of 5 to 50 weight percent, such as from 5 to 30 weight percent, based on the total weight of the powder coating composition.

These thermoset powder coating compositions can optionally include other materials such as other pigments, fillers, light stabilizers, flow modifiers, anti-popping agents, and anti-oxidants. Suitable pigments include, for example, titanium dioxide, ultramarine blue, phthalocyanine blue, phthalocyanine green, carbon black, graphite fibrils, black iron oxide, chromium green oxide, ferride yellow and quindo red. In certain embodiments, these other pigments are not nanoparticles.

Anti-popping agents can be added to the composition to allow any volatile material to escape from the film during baking. Benzoin is a commonly preferred anti-popping agent and when used is generally present in amounts of from 0.5 to 3.0 percent by weight based on total weight of the powder coating composition.

Such powder coating compositions may also include fumed silica and/or fumed aluminum oxide or the like to reduce caking of the powder during storage. An example of a fumed silica is sold by Cabot Corporation under the trademark CAB-O-SIL silica. An example of fumed aluminum oxide is sold by Evonik Corporation under the trademark AEROXIDE, for example, AEROXIDE Aluminum Oxide C. The fumed silica and/or fumed aluminum oxide may be present in amounts ranging from 0.1 to 1 percent by weight based on total weight of the powder coating formulation.

The polymer-enclosed color-imparting nanoparticles may be incorporated into the powder coating composition by any of a variety of methods. For example, in embodiments wherein the polymer-enclosed nanoparticles comprise a friable polymer, the polymer-enclosed color-imparting nanoparticles and other coating components are all embodied in a dried, particulate form, blended together, and then melt blended in an extruder. In other embodiments, however, such as those cases wherein an aqueous dispersion of polymer-enclosed nanoparticles is used that does not comprise a friable polymer, the polymer-enclosed color-imparting nanoparticles are incorporated into the powder coating composition by a method comprising (1) introducing to an extruder powder coating composition components comprising: (a) an aqueous dispersion of polymer-enclosed color-imparting nanoparticles, and (b) dry materials; (2) blending (a) and (b) in the extruder; (3) devolatilizing the blend to form an extrudate; (4) cooling the extrudate, and (5) milling the extrudate to a desired particle size. As used herein, the term “devolatilizing” means to remove volatile materials, including water and organic solvents. In certain embodiments, such powder coating compositions are made by a method and/or apparatus described in U.S. Patent Application Publication Nos. 2005/0212159A1; 2005/0212171A1; and/or 2005/0213423A1, the relevant disclosures of which being incorporated herein by reference.

In the foregoing methods, the dry materials may include the particulate film-forming resin described earlier as well as any other composition additives. The dry materials may be first blending in a high shear mixer such as a planetary mixture. In certain embodiments, the dry materials and the aqueous dispersion of the present invention are then blended in an extruder at a temperature ranging from 80° C. to 150° C. The extrudate is then cooled and pulverized into a particulate blend. In certain embodiments, the average particle size of the extrudate after if has been pulverized into particulate form ranges from 1 to 200 microns, such as from 10 to 100 microns, such as from 15 to 50 microns.

As mentioned, each one of the thermoset powder coating compositions provides a finished decorative and durable coating when deposited onto a substrate and cured. As used herein, the term “finished decorative and durable coating” refers to a finished coating, i.e., the coating is at a colorant, i.e., pigment, to film-forming resin concentration that is suitable for a powder coating composition in its final form as it is applied to a substrate; the colorant concentration is not at a concentration higher than what is to be applied to a substrate; the finished coating is both decorative, i.e., it provides a desired appearance to the substrate, and durable, i.e., it does not significantly chip, peel, mar, or delaminate when subjected to environmental conditions, such as humidity and abrasion typically experienced by a coating, such as coatings used on automotive and truck components, such as bodies, door panels, cabs, trailer bodies; airplane components, such as fuselage and wings; architectural components; consumer electronic equipment, such as computers and telephones; as well as other articles. As a result, the “finished decorative and durable coatings” of the present invention are distinct from decorative coatings formed from the use of dyes or inks that are not durable as well as from coatings that are at a higher colorant concentration than what is to be subsequently applied to a substrate.

Because each one of the thermoset powder coating compositions provides a finished decorative and durable coating when deposited onto a substrate and cured, no further ingredients are necessary to be combined with the thermoset powder coating compositions in order to provide a cured coating layer. In other words, each of the powder coating compositions of the methods of the present invention is a complete coating composition itself and may be applied as a coating layer without the addition of any other ingredients.

As would be recognized, because each one of the thermoset powder coating compositions provides a finished decorative and durable coating as described above, the thermoset powder coating composition formed from a mixture of one or more of the plurality of thermoset powder coating compositions dispensed according to the methods of the present invention also provides a finished decorative and durable coating when deposited onto a substrate and cured.

As mentioned above, in certain embodiments of the methods of the present invention, in addition to the containers holding the thermoset powder coating compositions, there may also be containers that hold various additives. These additives include materials other than thermoset powder coating compositions, and the additives are not necessary to the formation of a finished decorative and durable coating when the thermoset powder coating compositions are applied to a substrate and cured. The additives may be added to the thermoset powder coating compositions to provide various desired appearance and/or properties to the coating film, for example, variations to gloss and/or texture; control of cure rates; UV durability; coefficient of friction; weatherability.

In accordance with certain embodiments of the methods of the present invention, a controlled amount of a thermoset powder coating composition comprising a colorant, a particulate film-forming resin, and a curing agent is metered into the common receptacle followed by metering a controlled amount of another thermoset powder coating composition comprising a colorant, a particulate film-forming resin, and a curing agent to form a mixture of the powder coating composition in the common receptacle. In certain embodiments, the particulate film-forming resin present in the first powder coating composition is the same as, or at least compatible with, the particulate film-forming resin present in the second powder coating composition.

In certain embodiments of the methods of the present invention, each one of the plurality of thermoset powder coating compositions has a different hue.

In other embodiments, at least two of the plurality of the thermoset powder coating compositions have different hues such that when combined to form a mixture, the mixture upon direct application to at least a portion of a substrate and cure, produces a decorative and durable coating having a homogeneous hue different from the hues of each of the individual thermoset powder coating compositions. As used herein, the term “direct application”, and the like, means that the powder coating composition need not be subject to the Extrusion Process prior to application. As used herein, the term “homogeneous hue different from the hues of each of the individual themoset powder coating compositions” means that the coating is recognized by a person as having a uniform hue that is different from the hues of each of the individual thermoset powder coating compositions when viewed with the naked eye at any distance from the coating, including distances of one foot or less. Stated differently, the coating does not have a “salt and pepper” appearance wherein each of the hues is distinguishable by visual examination with the naked eye.

In yet other embodiments of the methods of the present invention, a controlled amount of a first thermoset powder coating composition having a first hue is metered into a common receptacle and a controlled amount of a second thermoset powder coating composition having a second hue different from the hue of the first thermoset powder coating composition is metered into the common receptacle to provide a mixture, wherein the mixture of the first powder coating with the second powder coating composition produces a powder coating composition that, upon direct application to at least a portion of a substrate and cure, produces a decorative and durable coating having a homogeneous hue different from the first hue and the second hue from which it is formed. As discussed above, the coating does not have a “salt and pepper” appearance of the first and second hues. As would be recognized, one or more additional thermoset powder coating compositions may also be added, each having a hue different from the hues of the first and second powder coating compositions, to provide a desired homogeneous hue.

In certain embodiments, the powder coating compositions provided from the plurality of thermoset powder coating compositions dispensed according to the methods of the present invention comprise a mixture of a first thermoset powder coating composition having a first hue and a second thermoset powder coating composition having a second hue different from the first hue. As used herein, the term “mixture” refers to a heterogeneous association of the first powder coating composition and the second powder coating composition, wherein the powder coating compositions are not chemically combined and can be separated by mechanical means. The first powder coating composition and the second powder coating composition may be dispensed according to the methods of the present invention, as described above, and subsequently mixed by any method, such as, for example, dry-blending methods using high speed agitators, such as a Henchsel mixer. In the methods of the present invention, as described herein, by dispensing thermoset powder coating compositions of a limited number of colors (fundamental colors) and by examining, in advance, the relation between the proportions of these colored powder coating compositions and the hues of the coatings obtained therefrom, a powder coating composition of virtually any desired hue can be produced by appropriately selecting the colored powder coating compositions, dispensing them in the proper proportion according to the present invention, and mixing them so as to give a desired homogeneous coating hue without the need to subject the mixture to the Extrusion Process.

In those methods of the present invention wherein the plurality of thermoset powder coating compositions are provided in a kit, upon dispensing and mixture of the contents of the first container in the kit with the contents of the second container in the kit, a powder coating composition is formed that, upon direct application to at least a portion of a substrate and cure, produces a decorative and durable coating having a homogeneous hue different from the first hue and the second hue.

The present invention is also directed to a method of coating a substrate comprising: (a) metering a controlled amount of at least one of a plurality of thermoset powder coating compositions from at least one of a plurality of containers to a common receptacle; and (b) applying the at least one thermoset powder coating composition from the common receptacle to a substrate, wherein at least one of the thermoset powder coating compositions comprises: (i) a colorant; (ii) a particulate film-forming resin; and (iii) a curing agent for the film-forming resin, and wherein the thermoset powder coating composition from the common receptacle provides a finished decorative and durable coating when deposited onto the substrate and cured.

In certain embodiments, more than one thermoset powder coating composition is present in the common receptacle. In these embodiments, the thermoset powder coating compositions in the common receptacle are mixed prior to application to the substrate.

The thermoset powder coating compositions provided from the plurality of thermoset powder coating compositions dispensed according to the methods of the invention can be applied to a variety of substrates including metallic substrates, for example, aluminum and steel substrates. The powder coating compositions are often applied by spraying, and in the case of a metal substrate, by electrostatic spraying, or by the use of a fluidized bed. The powder coating compositions can be applied in a single sweep or in several passes to provide a film having a thickness after cure of from about 1 to 10 mils (25 to 250 micrometers), usually about 2 to 4 mils (50 to 100 micrometers). In many cases, after application of the powder coating composition, the coated substrate is heated to a temperature sufficient to cure the coating, often to a temperature ranging from 250° F. to 500° F. (121.1° C. to 260.0° C.) for 1 to 60 minutes, such as 300° F. to 400° F. (148.9° C. to 204.4° C.) for 15 to 30 minutes.

As a result, the present invention is also directed to a substrate at least partially coated with a powder coating composition deposited from the plurality of thermoset powder coating compositions dispensed according to the methods of the present invention. In certain embodiments, the powder coating composition provided from the plurality of thermoset powder coating compositions dispensed according to the methods of the present invention and coated onto a substrate is a finished decorative and durable coating having a homogeneous hue. The decorative and durable coating is deposited directly from the plurality of thermoset coating compositions comprising a mixture of a first thermoset powder coating composition having a first hue and a second thermoset powder coating composition having a second hue different from the first hue, wherein the first powder coating composition and/or the second powder coating composition comprises polymer-enclosed color-imparting nanoparticles and a particulate film-forming resin. In the articles of the present invention, the homogeneous hue is different than the first hue and the second hue.

In certain embodiments, the decorative and durable coating deposited from the plurality of thermoset coating compositions dispensed according to the methods of the present invention is a non-hiding coating. As used herein, the term “non-hiding coating” refers to a coating layer deposited upon a substrate wherein the surface beneath the coating layer is visible to the naked eye. In certain embodiments of the present invention, the surface beneath the non-hiding coating layer is visible when the non-hiding layer is applied at a dry film thickness of 0.5 to 5.0 mils (12.7 to 127 microns). One way to assess non-hiding is by measurement of opacity. As used herein, “opacity” refers to the degree to which a material obscures a substrate.

“Percent opacity” refers herein to the ratio of the reflectance of a dry coating film over a black substrate of 5% or less reflectance, to the reflectance of the same coating film, equivalently applied and dried, over a substrate of 85% reflectance. The percent opacity of a dry coating film will depend on the dry film thickness of the coating and the concentration of color-imparting nanoparticles. In certain embodiments of the present invention, the color-imparting non-hiding coating layer has a percent opacity of no more than 90 percent, such as no more than 50 percent, at a dry film thickness of one (1) mil (about 25 microns).

In certain embodiments, the powder coating compositions provided from the plurality of thermoset powder coating compositions dispensed according to the methods of the present invention are deposited over a reflective surface. In these embodiments, the coating deposited over the reflective surface is a non-hiding coating as described above. As used herein, the term “reflective surface” refers to a surface comprising a reflective material having a total reflectance of at least 30%, such as at least 40%. “Total reflectance” refers herein to the ratio of reflected light from an object relative to the incident light that impinges on the object in the visible spectrum integrating over all viewing angles. “Visible spectrum” refers herein to that portion of the electromagnetic spectrum between wavelengths 400 and 700 nanometers. “Viewing angle” refers herein to the angle between the viewing ray and a normal to the surface at the point of incidence. The reflectance values described herein may be determined, for example, by using a Minolta Spectrophotometer CM-3600d according to the manufacturer supplied instructions.

In certain embodiments, the reflective surface comprises a substrate material such as, for example, polished aluminum, cold roll steel, chrome-plated metal, or vacuum deposited metal on plastic, among others. In other embodiments, the reflective surface may comprise a previously coated surface which may, for example, comprise a reflective coating layer deposited from a coating composition, such as, for example, a silver metallic basecoat layer, a colored metallic basecoat layer, a mica containing basecoat layer, or a white basecoat layer, among others.

Such reflective coating layers may be deposited from a film-forming composition that may, for example, include any of the film-forming resins typically used in protective coating compositions. For example, the film-forming composition of the reflective coating may comprise a resinous binder and one or more pigments to act as the colorant. Useful resinous binders include, but are not limited to, acrylic polymers, polyesters, including alkyds and polyurethanes. The resinous binders for the reflective coating composition may, for example, be embodied in a powder coating composition, an organic solvent-based coating composition or a water-based coating composition.

As noted, the reflective coating composition can contain pigments as colorants. Suitable pigments for the reflective coating composition include, for example, metallic pigments, which include aluminum flake, copper or bronze flake and metal oxide coated mica; non-metallic color pigments, such as titanium dioxide, iron oxide, chromium oxide, lead chromate, and carbon black; as well as organic pigments, such as, for example, phthalocyanine blue and phthalocyanine green.

The reflective coating composition can be applied to a substrate by any conventional coating technique such as brushing, spraying, dipping or flowing, among others. The usual spray techniques and equipment for air spraying, airless spraying and electrostatic spraying in either manual or automatic methods can be used. During application of the basecoat to the substrate, the film thickness of the basecoat formed on the substrate often ranges from 0.1 to 5 mils (2.5 to 127 micrometers), or 0.1 to 2 mils (2.5 to 50.8 micrometers).

After forming a film of the reflective coating on the substrate, the reflective coating can be cured or alternatively given a drying step in which solvent is driven out of the basecoat film by heating or an air drying period before application of subsequent coating compositions. Suitable drying conditions will depend on the particular basecoat composition, and one the ambient humidity if the composition is water-borne, but often, a drying time of from 1 to 15 minutes at a temperature of 75° F. to 200° F. (21° C. to 93° C.) will be adequate.

As mentioned above, the reflective surfaces are at least partially coated with a non-hiding coating layer deposited from a powder coating composition provided from a plurality of thermoset powder coating compositions dispensed according to the methods of the present invention. In certain embodiments, a clearcoat layer is deposited over at least a portion of the non-hiding coating layer. The clearcoat layer may be deposited from a composition that comprises any typical film-forming resin and can be applied over the color-imparting non-hiding layer to impart additional depth and/or protective properties to the surface underneath. The resinous binders for the clearcoat can be embodied as a powder coating composition, an organic solvent-based coating composition, or a water-based coating composition. Optional ingredients suitable for inclusion in the clearcoat composition include those which are well known in the art of formulating surface coatings, such as those materials described earlier. The clearcoat composition can be applied to a substrate by any conventional coating technique such as brushing, spraying, dipping or flowing, among others.

The thermoset powder coating compositions provided from the plurality of thermoset powder coating compositions dispensed according to the methods of the present invention may be used to form a single decorative and durable coating, for example, a monocoat, a base coat in a two-layered system or both; or as one or more layers of a multi-layered system including a clear top coating composition, a colorant layer and/or a base coating composition, and/or a primer layer, including, for example, an electrodeposition primer and/or a primer-surfacer layer.

The present invention is also directed to substrates at least partially coated with a multi-layer composite coating wherein at least one coating layer is deposited from a powder coating composition provided from the plurality of thermoset powder coating compositions dispensed according to the methods of the present invention. In certain embodiments, for example, the powder coating composition provided from the methods of the present invention comprises the basecoat layer in a multi-layer composite coating comprising a basecoat and a topcoat. As a result, in these embodiments, after application and curing of the powder coating composition provided from the methods of the present invention, at least one topcoat layer can be applied to the basecoat layer. The topcoat can, for example, be deposited from a powder coating composition, an organic solvent-based coating composition or a water-based coating composition, as is well known in the art. The film-forming composition of the topcoat can be any of the compositions useful in coatings applications, including, for example, a film-forming composition that comprises a resinous binder selected from acrylic polymers, polyesters, including alkyds, and polyurethanes. The topcoat composition can be applied by any conventional coating technique such as brushing, spraying, dipping or flowing, but they are most often applied by spraying. The usual spray techniques and equipment for air spraying, airless spray and electrostatic spraying in either manual or automatic methods can be used.

In certain embodiments, coatings deposited from a powder coating composition provided from the plurality of thermoset powder coating compositions comprising polymer-enclosed color-imparting nanoparticles having a maximum haze of 10% dispensed according to the methods of the present invention exhibit a “richer” color as compared to similar powder coating compositions provided from thermoset powder coating compositions that do not include a plurality of polymer-enclosed color-imparting nanoparticles having a maximum haze of 10%, such as those described above. As used herein, the term “color richness” refers to the L* value in the CIELAB color system as described in U.S. Pat. No. 5,792,559 at col. 1, lines 34 to 64, the cited portion of which being incorporated herein by reference, wherein a lower L* value corresponds to a higher level of color richness. For purposes of the present invention, color measurements at various angles can be made using an X-RITE spectrophotometer, such as an MA681 Multi-angle spectrophotometer, commercially available from X-Rite Instruments, Inc.

The inventors have discovered that, unlike prior art powder coating compositions, the powder coating compositions provided from the plurality of thermoset powder coating compositions comprising a colorant, a particulate film-forming resin, and a curing agent for the film-forming resin dispensed according to the methods of the present invention are capable of producing coatings that exhibit color properties similar to coatings deposited from liquid coating compositions. As a result, the powder coating compositions dispensed according to the methods of the present invention can be used for color matching of coatings deposited from liquid coating compositions. These color-matching methods comprise: (a) determining the visible color of the preselected liquid coating by measuring the absorbance or reflectance of the preselected liquid coating; (b) determining a recipe and/or formula for a thermoset powder coating composition wherein a coating deposited from the thermoset powder coating composition matches the visible color of the preselected liquid coating, and wherein the recipe and/or formula contains a list of a plurality of thermoset powder coating compositions comprising polymer-enclosed color-imparting nanoparticles and particulate film-forming resin; (c) dispensing the plurality of thermoset powder coating compositions comprising a colorant, a particulate film-forming resin, and a curing agent for the film-forming resin present on the list according to the methods of the present invention. In these methods, the absorbance or reflectance of the preselected liquid coating is determined using a spectrophotometer (as described above) and a curve of the absorbance or reflectance across the range of wavelengths corresponding to the visible spectrum is produced. This curve is referred to as the visible absorbance or reflectance spectrum. A powder coating composition is produced from the plurality of thermoset powder coating compositions dispensed according to the methods of the present invention such that the coating deposited from the powder coating composition has a visible absorbance or reflectance spectrum closely matching that of the preselected liquid coating.

The present invention is also directed to a system for dispensing a plurality of thermoset powder coating compositions, the system comprising: (a) a plurality of containers having at least one thermoset powder coating composition therein; and (b) a means for metering a controlled amount of at least one of the thermoset powder coating compositions from at least one of the containers to a common receptacle, wherein the thermoset powder coating compositions comprise: (i) a colorant; (ii) a particulate film-forming resin; and (iii) a curing agent for the film-forming resin, and wherein each one of the thermoset powder coating compositions provides a finished decorative and durable coating when deposited onto a substrate and cured.

Whereas particular embodiments of this invention have been described above for purposes of illustration, it will be evident to those skilled in the art that numerous variations of the details of the present invention may be made without departing from the invention as defined in the appended claims.

What is claimed is:

1. A method of dispensing a thermoset powder coating composition, comprising:
metering a controlled amount of at least one of a plurality of thermoset powder coating compositions from at least one of a plurality of containers to a common receptacle, wherein at least one of the plurality of thermoset powder coating compositions comprises:
(a) a colorant;
(b) a particulate film-forming resin; and
(c) a curing agent for the film-forming resin, and
wherein each one of the thermoset powder coating compositions provides a finished decorative and durable coating when deposited onto a substrate and cured.

2. The method of claim 1, wherein the metering step comprises:
drawing a desired amount of the thermoset powder coating composition from the container; and
dispensing the desired amount of the thermoset powder coating composition into the common receptacle.

3. The method of claim 2, wherein the metering step further comprises:
measuring a first amount of the thermoset powder coating composition dispensed into the common receptacle;
comparing the first amount dispensed to the desired amount to calculate a difference between the first amount dispensed and the desired amount;
using the difference between the first amount dispensed and the desired amount to calculate a second amount of the thermoset powder coating composition to be dispensed; and
dispensing the second amount of the thermoset powder coating composition into the common receptacle to provide the desired amount.

4. The method of claim 1 further comprising metering a controlled amount of at least one additive from at least one additive container to the common receptacle.

5. The method of claim 1, wherein each of the plurality of containers has one thermoset powder coating composition disposed therein.

6. The method of claim 1, wherein the plurality of thermoset powder coating compositions comprise the same particulate film-forming resin.

7. The method of claim 1, wherein the colorant comprises polymer-enclosed color-imparting nanoparticles.

8. The method of claim 7, wherein the nanoparticles comprise organic nanoparticles.

9. The method of claim 7, wherein the polymer-enclosed color-imparting nanoparticles comprise a friable polymer.

10. The method of claim 1, wherein each one of the plurality of thermoset powder coating compositions has a different hue.

11. The method of claim 1, wherein at least two of the plurality of the thermoset powder coating compositions have different hues such that when combined to form a mixture, the mixture, upon direct application to at least a portion of the substrate and cure, produces a decorative and durable coating having a homogeneous hue different from the hues of each of the individual thermoset powder coating compositions.

12. A method of coating a substrate comprising:
(a) dispensing a thermoset powder coating composition according to the method of claim 1; and
(b) applying the thermoset powder coating composition from the common receptacle to a substrate.

13. The method of claim 12, wherein more than one thermoset powder coating composition is metered into the common receptacle.

14. The method of claim 12, wherein the thermoset powder coating compositions in the common receptacle are mixed prior to applying to the substrate.

15. A method of dispensing a plurality of thermoset powder coating compositions, comprising:
metering a controlled amount of a first thermoset powder coating composition having a first hue from a first container and a second powder coating composition having a second hue different from the hue of the first powder coating composition from a second container to a common receptacle to form a mixture, wherein the first powder coating composition and the second powder coating composition each comprise:
(a) a colorant;
(b) a particulate film-forming resin; and
(c) a curing agent for the film-forming resin,
wherein each of the first thermoset powder coating composition and the second thermoset powder coating composition provides a finished decorative and durable coating when deposited onto a substrate and cured, and
wherein the mixture provides a finished decorative and durable coating having a homogeneous hue different from the hue of the first powder coating composition and the hue of the second powder coating composition when the mixture is applied to a substrate and cured.

16. The method of claim 15, wherein the metering step comprises:
drawing a desired amount of the first thermoset powder coating composition from the first container;
dispensing the desired amount of the first thermoset powder coating composition into the common receptacle;
drawing a desired amount of the second thermoset powder coating composition from the second container; and
dispensing the desired amount of the second thermoset powder coating composition into the common receptacle.

17. The method of claim 16, wherein the metering step further comprises:
measuring a first amount of the first thermoset powder coating composition dispensed into the common receptacle;
comparing the first amount dispensed to the desired amount to calculate a difference between the first amount dispensed and the desired amount;
using the difference between the first amount dispensed and the desired amount to calculate a second amount of the first thermoset powder coating composition to be dispensed; and
dispensing the second amount of the first thermoset powder coating composition into the common receptacle to provide the desired amount;
measuring a first amount of the second thermoset powder coating composition dispensed into the common receptacle;
comparing the first amount dispensed to the desired amount to calculate a difference between the first amount dispensed and the desired amount;
using the difference between the first amount dispensed and the desired amount to calculate a second amount of the second thermoset powder coating composition to be dispensed; and
dispensing the second amount of the second thermoset powder coating composition into the common receptacle to provide the desired amount.

18. The method of claim 15, wherein the colorant comprises polymer-enclosed color-imparting nanoparticles.

19. The method of claim 18, wherein the nanoparticles comprise organic nanoparticles.

20. A system for dispensing a plurality of thermoset powder coating compositions, the system comprising:
(a) a plurality of containers having at least one thermoset powder coating composition therein; and
(b) a means for metering a controlled amount of at least one of the thermoset powder coating compositions from at least one of the containers to a common receptacle,
wherein the thermoset powder coating compositions comprise:
(i) a colorant;
(ii) a particulate film-forming resin; and
(iii) a curing agent for the film-forming resin, and
wherein each one of the thermoset powder coating compositions provides a finished decorative and durable coating when deposited onto a substrate and cured.
